(19) United States
(12) Patent Application Publication
(10) Pub. No.: US 2026/0198242 A1
(43) Pub. Date: Jul. 9, 2026

(54) METHOD OF MANUFACTURING A SEMICONDUCTOR DEVICE

(71) Applicant: Taiwan Semiconductor Manufacturing Company, Ltd., Hsinchu (TW)

(72) Inventors: Chih-Cheng LIU, Hsinchu (TW); Chun Lin HSIANG, Hsinchu (TW); Jr-Hung LI, Hsinchu (TW); Chung-Chi KO, Hsinchu (TW); Yung-Cheng LU, Hsinchu (TW)

(73) Assignee: Taiwan Semiconductor Manufacturing Company, Ltd., Hsinchu (TW)

(21) Appl. No.: 19/204,148

(22) Filed: May 9, 2025

Related U.S. Application Data
(60) Provisional application No. 63/742,245, filed on Jan. 6, 2025.

(51) Int. Cl. H01L 21/308; G03F 7/16; H01L 21/027; H01L 21/311; H01L 21/3213

(52) U.S. Cl. CPC H10P 50/695; G03F 7/162; G03F 7/168; H10P 50/71; H10P 50/73; H10P 76/2043

(57) ABSTRACT

A method of manufacturing a semiconductor device includes depositing a photoresist composition over a target layer on a substrate to form a photoresist layer. The photoresist layer is selectively exposed to actinic radiation. A vacuum is applied to the photoresist layer after selectively exposing the photoresist layer. O₂ and H₂O are introduced to the selectively exposed photoresist layer. The selectively exposed photoresist layer is baked. The photoresist layer is developed after baking the photoresist layer. The target layer is etched using the photoresist layer as an etch mask.

### CROSS-REFERENCE TO RELATED APPLICATIONS

This application claims priority to U.S. Provisional Ser. No. 63/742,245 filed Jan. 6, 2025, the entire disclosure of which is incorporated herein by reference.

### BACKGROUND

The semiconductor integrated circuit (IC) industry has experienced rapid growth. Technological advances in IC materials and design have produced generations of ICs where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs. For continued advances to be realized, similar developments in IC processing and manufacturing are needed. However, as the size of individual devices has decreased, process windows for photolithographic processing has become tighter and tighter. As such, advances in the field of photolithographic processing are necessary to maintain the ability to scale down the devices, and further improvements are needed in order to meet the desired design criteria such that the march towards smaller and smaller components may be maintained.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a process flow of manufacturing a semiconductor device according to embodiments of the disclosure.

FIG. 2 shows a process stage of a sequential operation according to an embodiment of the disclosure.

FIGS. 3A and 3B show a process stage of a sequential operation according to embodiments of the disclosure.

FIG. 4 shows a process stage of a sequential operation according to an embodiment of the disclosure.

FIGS. 5A and 5B show a process stage of a sequential operation according to embodiments of the disclosure.

FIG. 6 shows a process stage of a sequential operation according to embodiments of the disclosure.

FIG. 7 shows a process stage of a sequential operation according to embodiments of the disclosure.

FIGS. 8A and 8B show organometallic precursors according to embodiments of the disclosure. FIG. 8C shows a reaction the organometallic precursors undergo when exposed to actinic radiation. FIG. 8D shows examples of organometallic precursors according to embodiments of the disclosure.

FIG. 9 illustrates a deposition apparatus according to embodiments of the disclosure.

FIG. 10 illustrates a post-exposure baking apparatus according to embodiments of the disclosure.

FIG. 11A shows a reaction the photoresist layer undergoes as a result of exposure to actinic radiation and heating according to an embodiment of the disclosure. FIG. 11B shows a reaction the photoresist layer undergoes as a result of exposure to actinic radiation and heating according to an embodiment of the disclosure.

FIGS. 12A and 12B illustrate a controller for controlling the photoresist deposition operation and/or the post-exposure baking operation and/or other baking operations during methods of the present disclosure.

FIG. 13 shows a process stage of a sequential operation according to an embodiment of the disclosure.

FIGS. 14A and 14B show a process stage of a sequential operation according to embodiments of the disclosure.

FIG. 15 shows a process stage of a sequential operation according to an embodiment of the disclosure.

FIGS. 16A and 16B show a process stage of a sequential operation according to embodiments of the disclosure.

FIG. 17 shows a process stage of a sequential operation according to embodiments of the disclosure.

FIG. 18 shows a process stage of a sequential operation according to embodiments of the disclosure.

FIGS. 19A and 19B show a process stage of a sequential operation according to embodiments of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper,” “top,” “bottom,” “middle,” and the like, may be used herein for ease of description to describe one element or feature's relationship to another element(s) or feature(s) as illustrated in the figures, and do not preclude additional structures above or below or between the stated feature. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations between the described operations, and the order of operations may be changed. In the present disclosure, a phrase “one of A, B and C” means “A, B and/or C (A, B, C, A and B, A and C, B and C, or A, B and C), and does not mean one element from A, one element from B and one element from C, unless otherwise described. In the following embodiments, materials, configurations, dimensions, processes and/or operations as described with respect to one embodiment (e.g., one or more figures) may be employed in the other embodiments, and detailed description thereof may be omitted.

To achieve smaller feature sizes and feature spacing in semiconductor devices improved contrast between exposed regions and non-exposed of a photoresist layer is desirable. Embodiments of this disclosure provide improved contrast between the exposed and non-exposed regions of the photoresist layer during semiconductor device fabrication. Embodiments of this disclosure provide improved integrity of the photoresist pattern and decreased line width roughness and line edge roughness, and scum reduction. Embodiments of the disclosure allow reduced exposure doses.

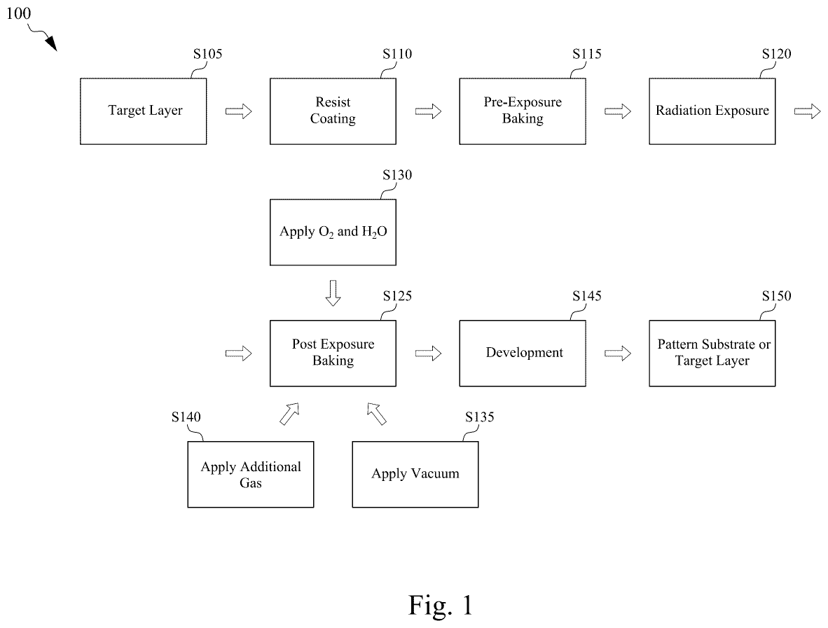

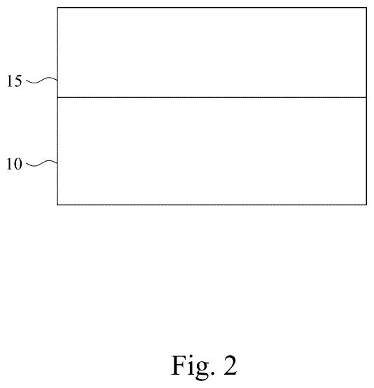

FIG. 1 illustrates a flowchart of methods 100 for a semiconductor device fabrication in accordance with some embodiments. FIGS. 2-18 illustrate sectional views of a semiconductor device at various fabrication stages in accordance with some embodiments. The methods 100 and systems utilized in the methods are collectively described with reference to these figures.

The method 100 includes an operation S105 of forming a target layer 60 over a substrate 10 in some embodiments. In some embodiments, the substrate 10 is a semiconductor substrate. In some embodiments, the semiconductor substrate 10 is a semiconductor wafer, such as a silicon wafer. In some embodiments, the target layer 60 is an insulating layer, in other embodiments, the target layer 60 is a semiconductor layer, and in other embodiments, the target layer 60 is a conductive layer.

A resist layer composition is subsequently coated on a surface of the substrate 10 or target layer 60 in operation S110, in some embodiments, to form a resist layer 15, as shown in FIG. 2. In some embodiments, the resist layer 15 is a photoresist layer. Then the resist layer 15 undergoes a first baking operation S115 (or pre-exposure baking operation) to evaporate solvents in the resist composition or cure the resist layer in some embodiments. The resist layer 15 is baked at a temperature and time sufficient to cure and dry the photoresist layer 15. In some embodiments, the resist layer is heated at a temperature of about 40° C. to about 150° C. for about 10 seconds to about 10 minutes.

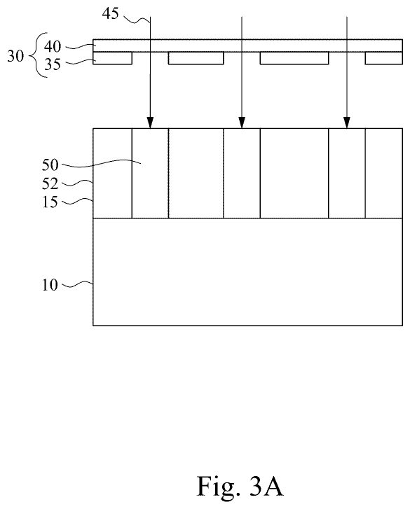

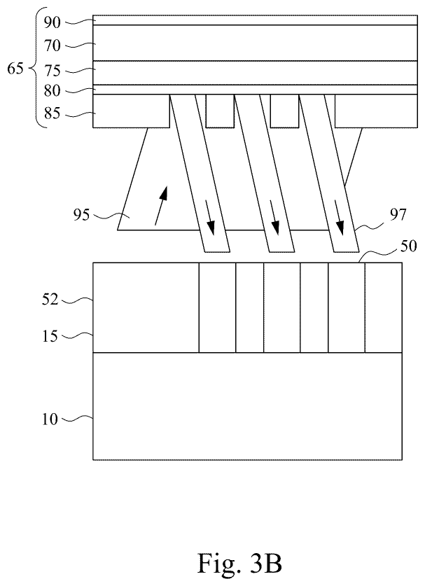

After the first (or pre-exposure) baking operation S115 of the photoresist layer 15, the photoresist layer 15 is selectively exposed to actinic radiation 45/97 (see FIGS. 3A and 3B) in operation S120. In some embodiments, the radiation is electromagnetic radiation, such as g-line (436 nm wavelength), i-line (365 nm wavelength), ultraviolet radiation, deep ultraviolet radiation, extreme ultraviolet radiation, or electron beam, or the like. In some embodiments, the radiation source is selected from the group consisting of a mercury vapor lamp, xenon lamp, carbon arc lamp, a KrF excimer laser light (248 nm wavelength), an ArF excimer laser light (193 nm wavelength), an F₂ excimer laser light (157 nm wavelength), or a CO₂ laser-excited Sn plasma (extreme ultraviolet, 13.5 nm wavelength).

As shown in FIG. 3A, the exposure radiation 45 passes through a photomask 30 before irradiating the photoresist layer 15 in some embodiments. In some embodiments, the photomask has a pattern to be replicated in the photoresist layer 15. The pattern is formed by an opaque pattern 35 on the photomask substrate 40, in some embodiments. The opaque pattern 35 may be formed by a material opaque to ultraviolet radiation, such as chromium, while the photomask substrate 40 is formed of a material that is transparent to ultraviolet radiation, such as fused quartz.

In some embodiments, the selective exposure of the photoresist layer 15 to form exposed regions 50 and unexposed regions 52 is performed using extreme ultraviolet lithography. In some embodiments of an extreme ultraviolet lithography operation, a reflective photomask 65 is used to form the patterned exposure light in some embodiments, as shown in FIG. 3B. The reflective photomask 65 includes a low thermal expansion glass substrate 70, on which a reflective multilayer 75 of Si and Mo is formed. A capping layer 80 and absorber layer 85 are formed on the reflective multilayer 75. A rear conductive layer 90 is formed on the back side of the low thermal expansion glass substrate 70. In extreme ultraviolet lithography, extreme ultraviolet radiation 95 is directed towards the reflective photomask 65 at an incident angle of about 6°. A portion 97 of the extreme ultraviolet radiation is reflected by the Si/Mo multilayer 75 towards the photoresist coated substrate 10, while the portion of the extreme ultraviolet radiation incident upon the absorber layer 85 is absorbed by the photomask. In some embodiments, additional optics, including mirrors, are between the reflective photomask 65 and the photoresist coated substrate.

The region of the photoresist layer exposed to radiation 50 undergoes a chemical reaction thereby changing its solubility in a subsequently applied developer relative to the region of the photoresist layer not exposed to radiation 52. In some embodiments, the portion of the photoresist layer exposed to radiation 50 undergoes a crosslinking reaction.

The amount of electromagnetic radiation can be characterized by a fluence or dose, which is obtained by the integrated radiative flux over the exposure time. Suitable radiation fluences range from about 1 mJ/cm² to about 150 mJ/cm² in some embodiments, from about 2 mJ/cm² to about 100 mJ/cm² in other embodiments, and from about 3 mJ/cm² to about 50 mJ/cm² in other embodiments. A person of ordinary skill in the art will recognize that additional ranges of radiation fluences within the explicit ranges above are contemplated and are within the present disclosure.

In some embodiments, the selective or patternwise exposure is performed by a scanning electron beam. With electron beam lithography, the electron beam induces secondary electrons, which modify the irradiated material. High resolution is achievable using electron beam lithography and the metal-containing resists disclosed herein. Electron beams can be characterized by the energy of the beam, and suitable energies range from about 5 V to about 200 kV (kilovolt) in some embodiments, and from about 7.5 V to about 100 kV in other embodiments. Proximity-corrected beam doses at 30 kV range from about 0.1 μC/cm² to about 100 μC/cm² in some embodiments, from about 0.5 μC/cm² to about 25 μC/cm² in other embodiments, and in other embodiments from about 1 μC/cm² to about 5 μC/cm². A person of ordinary skill in the art can compute corresponding doses at other beam energies based on the teachings herein and will recognize that additional ranges of electron beam properties within the explicit ranges above are contemplated and are within the present disclosure.

Next, the photoresist layer 15 undergoes a second baking (or post-exposure bake (PEB)) in operation S125. In some embodiments, the photoresist layer 15 is heated at a temperature of about 20° C. to about 400° C. for about 20 seconds to about 1500 seconds. In other embodiments, the photoresist layer 15 is heated at a temperature ranging from about 50° C. to about 250° C. for about 50 seconds to about 1000 seconds. The post-exposure baking assists in crosslinking the radiation exposed photoresist in some embodiments. In some embodiments, the post-exposure baking assists in generating, dispersing, and reacting chemical reactants formed during the actinic radiation exposure, including acids or bases generated by the action of the actinic radiation. The PEB helps to create or enhance chemical reactions, which generate chemical differences between the exposed region 50 and the unexposed region 52 within the photoresist layer.

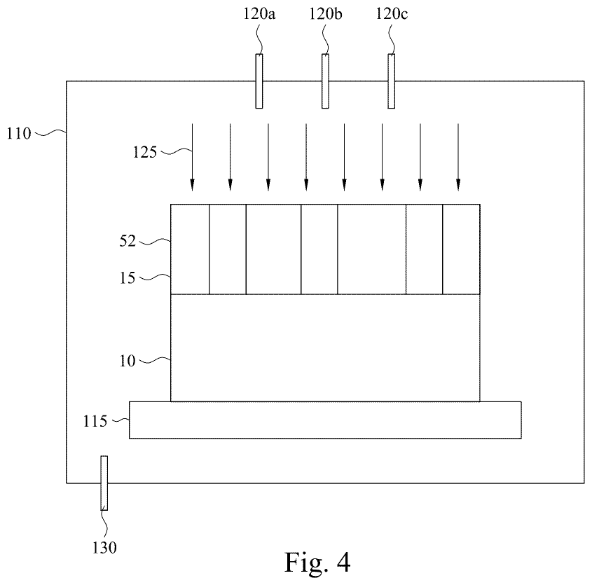

In some embodiments, a mixture 125 of oxygen (O₂) and water (H₂O) is applied to the resist layer 15 during the PEB in operation S130, as illustrated in FIG. 4. The water is applied as a vapor, gas (steam), or a fine mist in some embodiments. The oxygen promotes crosslinking in the actinic radiation exposed areas 50 of the photoresist layer during the PEB, while the water suppresses crosslinking reactions in the actinic radiation non-exposed areas 52 of the photoresist layer. As shown in FIG. 4, the PEB operation occurs in a baking chamber 110 in some embodiments. The resist-coated substrate is supported on a substrate support stage 115 in the baking chamber 110. In some embodiments, the substrate support stage 115 includes a heater for heating the resist-coated substrate during the PEB operation. The water and oxygen may be introduced into the chamber 110 via inlets 120a and 120b, respectively.

The baking chamber 110 may be a vacuum chamber. In some embodiments, the PEB operation S125 is performed at reduced pressure. In some embodiments, a vacuum is applied to the baking chamber 110 in operation S135 before and/or during the PEB operation S125. The baking chamber 110 may be evacuated through an exhaust 130 using a vacuum pump.

In some embodiments, an additional gas may be applied in operation S140 during the PEB operation S125. In some embodiments, the additional gas includes at least one of SO₂, CO₂, NH₃, and acetic acid. The additional gas may assist the crosslinking reaction in the actinic radiation exposed areas 50 of the photoresist layer.

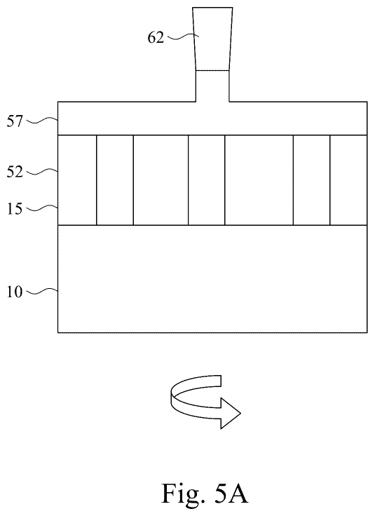

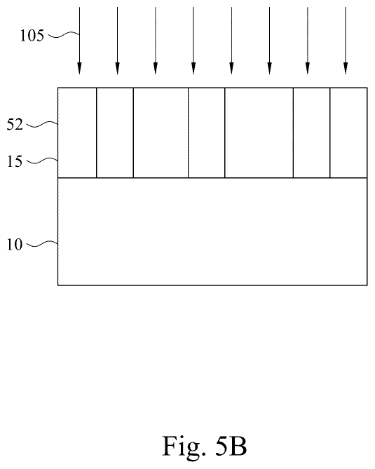

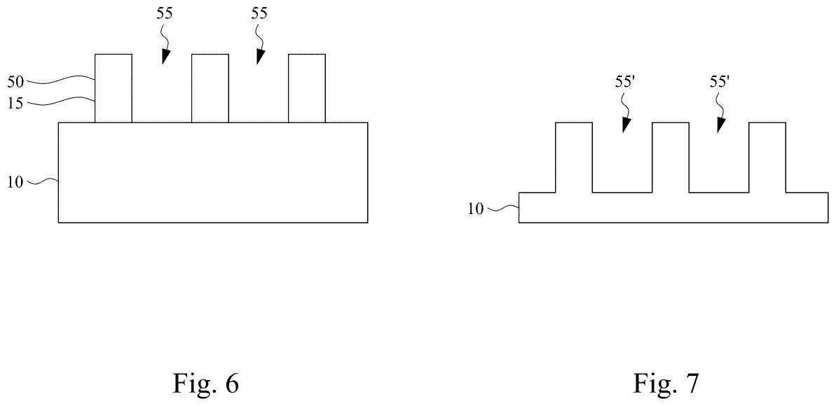

The selectively exposed photoresist layer is subsequently developed by applying a developer to the selectively exposed photoresist layer in operation S145. As shown in FIG. 5A, a developer 57 is supplied from a dispenser 62 to the photoresist layer 15. In some embodiments, the developer 105 is a dry developer, as shown in FIG. 5B. In some embodiments, the unexposed region 52 of the photoresist layer is removed by the developer 57, 105 forming a pattern of openings 55 in the photoresist layer 15 exposing portions of the substrate 10, as shown in FIG. 6.

In some embodiments, the photoresist developer 57 includes a solvent, and an acid or a base. In some embodiments, the concentration of the solvent is from about 60 wt. % to about 99 wt. % based on the total weight of the photoresist developer. The acid or base concentration is from about 0.001 wt. % to about 20 wt. % based on the total weight of the photoresist developer. In certain embodiments, the acid or base concentration in the developer is from about 0.01 wt. % to about 15 wt. % based on the total weight of the photoresist developer.

In some embodiments, the developer 57 is applied to the photoresist layer 15 using a spin-on process. In the spin-on process, the developer 57 is applied to the photoresist layer 15 from above the photoresist layer 15 while the photoresist-coated substrate is rotated, as shown in FIG. 5A. In some embodiments, the developer 57 is supplied at a rate of between about 5 ml/min and about 800 ml/min, while the photoresist coated substrate 10 is rotated at a speed of between about 100 rpm and about 2000 rpm. In some embodiments, the developer is at a temperature of between about 10° C. and about 80° C. during the development operation. The development operation continues for between about 30 seconds to about 10 minutes in some embodiments.

In some embodiments, the developer 57 is an organic solvent. The organic solvent can be any suitable solvent. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, 4-methyl-2-pentanol, acetone, methyl ethyl ketone, dimethylformamide (DMF), isopropanol (IPA), tetrahydrofuran (THF), methyl isobutyl carbinol (MIBC), n-butyl acetate (nBA), 2-heptanone (MAK), tetrahydrofuran (THF), and dioxane.

While the spin-on operation is one suitable method for developing the photoresist layer 15 after exposure, it is intended to be illustrative and is not intended to limit the embodiment. Rather, any suitable development operations, including dip processes, puddle processes, and spray-on methods, may alternatively be used. All such development operations are included within the scope of the embodiments.

In some embodiments, a dry developer 105 is applied to the selectively exposed photoresist layer 15, as shown in FIG. 5B. In some embodiments, the dry developer 105 is a plasma or chemical vapor, and the dry development operation S145 is a plasma etching or chemical etching operation. The dry development uses the differences related to the composition, extent of cross-linking, and film density to selectively remove the desired portions of the resist. In some embodiments, the dry development processes uses either a gentle plasma (high pressure, low power) or a thermal process in a heated vacuum chamber while flowing a dry development chemistry, such as Cl₂, CHCl₃, CH₂Cl₂, CH₄, CF₄, N₂, BF₃, BCl₃, CCl₄, HCl, O₂, NF₃, NH₃, N₂H₂, HBr and NO₂, or other Lewis Acid in the vapor state. In some embodiments, the developer 105 removes the unexposed material, leaving behind a pattern of the exposed film that is transferred into the underlying layers by plasma-based etch processes.

In some embodiments, the dry development includes plasma processes, including transformer coupled plasma (TCP), inductively coupled plasma (ICP) or capacitively coupled plasma (CCP). In some embodiments, the plasma process is conducted at a pressure ranging from about 5 mTorr to about 20 mTorr, at a power level from about 250 W to about 1000 W, at a temperature ranging from about 0° C. to about 300° C., and at flow rate of about 100 to about 1000 sccm, for about 1 to about 3000 seconds.

In some embodiments, the dry development reaction is as follows:
MOₓC_{y}+HX→MₓC_{y}+H₂O; where MOₓC_{y} is the photoresist, HX is the developer gas, and MₓC_{y} is the development product, which is a gas at low pressure.

In some embodiments, the pattern of openings 55 in the photoresist layer 15 is extended into the substrate 10, or target layer 60 (see FIG. 18) in operation S150 to create a pattern of openings 55′ in the substrate 10 or target layer 60, thereby transferring the pattern in the photoresist layer 15 into the substrate 10 or target layer 60, as shown in FIGS. 7 and 18. The pattern is extended into the substrate or target layer by etching, using one or more suitable etchants. In some embodiments, the patterned photoresist layer pattern 15 is at least partially removed during the etching operation. In some embodiments, the patterned photoresist layer 15 is removed after etching the substrate 10 or target layer by using a suitable photoresist stripper solvent or by a photoresist ashing operation.

In some embodiments, the substrate 10 includes a single crystalline semiconductor layer on at least its surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. In some embodiments, the substrate 10 is a silicon layer of an SOI (silicon-on insulator) substrate. In certain embodiments, the substrate 10 is made of crystalline Si.

The substrate 10 may include in its surface region, one or more buffer layers (not shown). The buffer layers can serve to gradually change the lattice constant from that of the substrate to that of subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In an embodiment, the silicon germanium (SiGe) buffer layer is epitaxially grown on the silicon substrate 10. The germanium concentration of the SiGe buffer layers may increase from 30 atomic % for the bottom-most buffer layer to 70 atomic % for the top-most buffer layer.

In some embodiments, the substrate 10 includes one or more layers of at least one metal, metal alloy, and metal nitride/sulfide/oxide/silicide having the formula MXₐ, where M is a metal and X is N, S, Se, O, Si, and a is from about 0.4 to about 2.5. In some embodiments, the substrate 10 includes titanium, aluminum, cobalt, ruthenium, titanium nitride, tungsten nitride, tantalum nitride, and combinations thereof.

In some embodiments, the substrate 10 includes a dielectric having at least a silicon or metal oxide or nitride of the formula MX_{b}, where M is a metal or Si, X is N or O, and b ranges from about 0.4 to about 2.5. In some embodiments, the substrate 10 includes silicon dioxide, silicon nitride, aluminum oxide, hafnium oxide, lanthanum oxide, and combinations thereof.

The photoresist layer 15 is a photosensitive layer that is patterned by exposure to actinic radiation. Typically, the chemical properties of the photoresist regions struck by incident radiation change in a manner that depends on the type of photoresist used. Photoresist layers 15 are either positive tone resists or negative tone resists. A positive tone resist refers to a photoresist material that when developed, the portions of the photoresist layer exposed to actinic radiation, such as UV light, are removed, while the region of the photoresist that is non-exposed (or exposed less) remains on the substrate after the development operation. A negative tone resist, on the other hand, refers to a photoresist material that when developed, the portions of the photoresist exposed to actinic radiation remain on the substrate after the development operation, while the region of the photoresist that is non-exposed (or exposed less) is removed during the development operation.

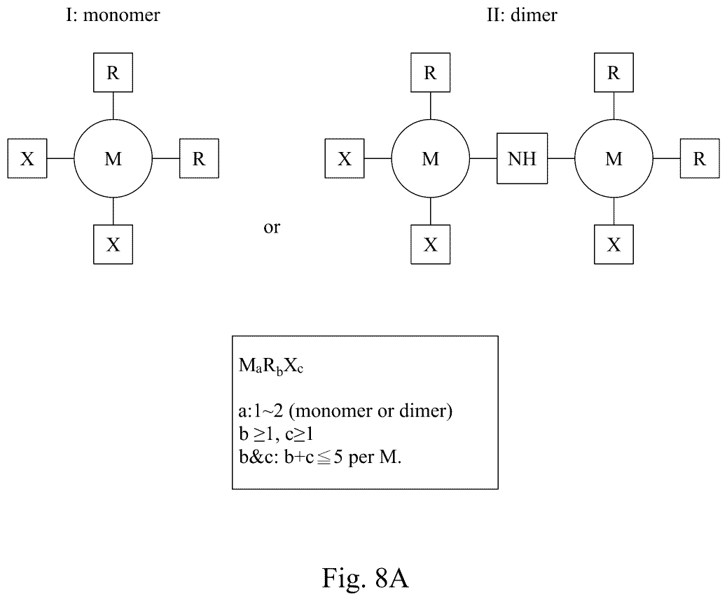

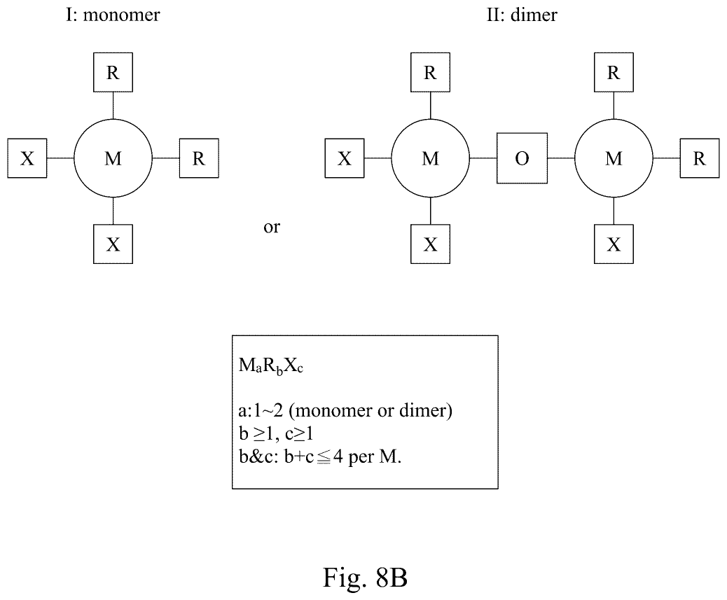

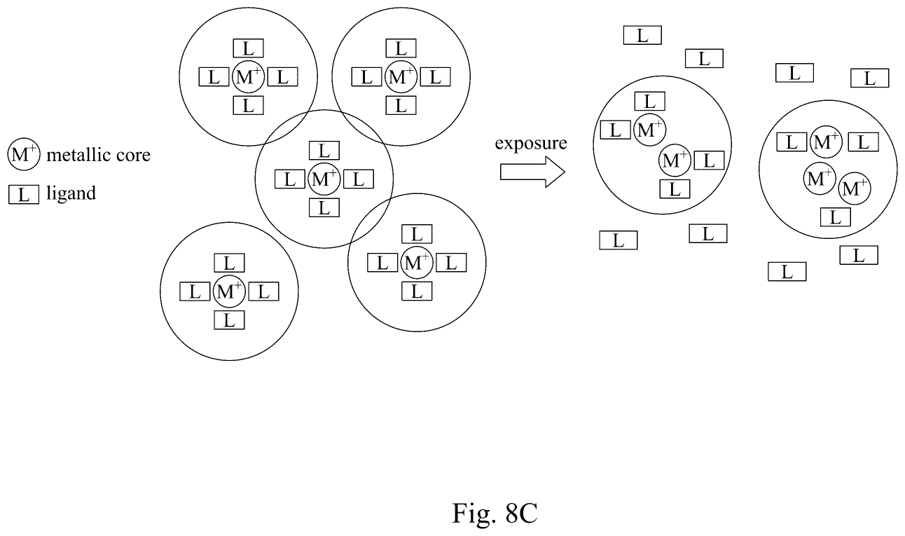

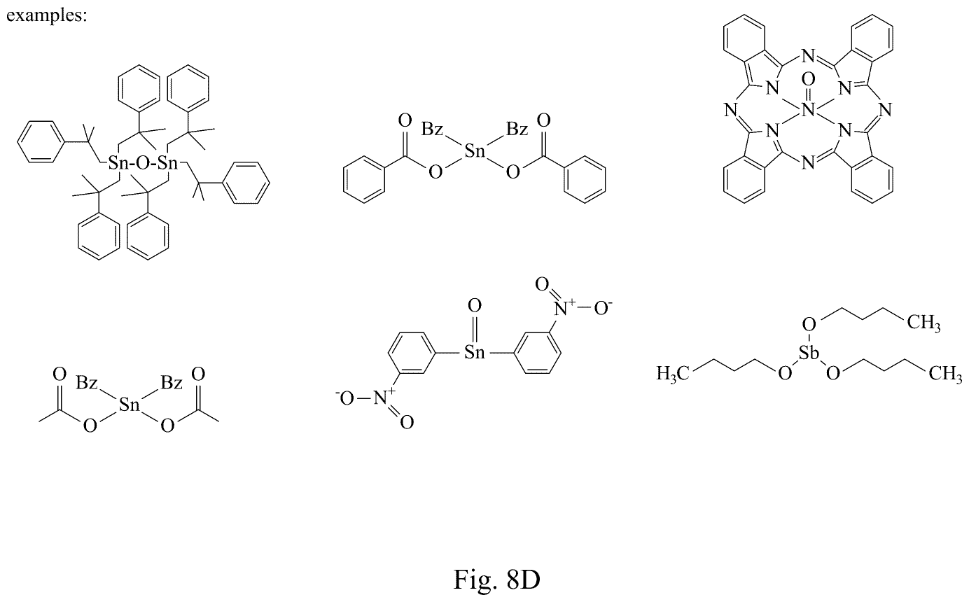

In some embodiments, the photoresist layer 15 is made of a photoresist composition, including a first compound or a first precursor and a second compound or a second precursor combined in a vapor state. The first precursor or first compound is an organometallic having a formula: MₐR_{b}X_{c} (a, b and c are natural number), as shown in FIGS. 8A and 8B, where M is one or more selected from the group consisting of Sn, Bi, Sb, In, Te, and oxides thereof; R is a substituted or unsubstituted alkyl, alkenyl, or carboxylate group. In some embodiments, X is a ligand, ion, or other substituent, which is reactive with the second compound or second precursor; and 1≤a≤2, b≥1, c≥1, and b+c≤4. In certain embodiments, b+c=4. In some embodiments, the alkyl, alkenyl, or carboxylate group is substituted with one or more fluoro groups. In some embodiments, the organometallic precursor is a dimer, as shown in FIG. 8A, where each monomer unit is linked by an amine group. In some embodiments, b=c=2. In other embodiments, the organometallic precursor is a dimer, as shown in FIG. 8B, where each monomer unit is linked by oxygen. In some embodiments, b=1 and c=3. Each monomer has a formula: MₐR_{b}X_{c}, as defined above.

In some embodiments, R in the formula MₐR_{b}X_{c} includes alkyl groups that are substituted by different electron-donating groups (EDG) and/or electron-withdrawing groups (EWG) to tune the bond dissociation energy to provide a bond that is cleaved by a low EUV dosage. In some embodiments, R is a substituted or unsubstituted C1-C20 alkyl group, including all isomers of C1-C20 alkyl groups. The EDG include oxido group (—O⁻), amino groups (−NH₂, —NHR, —NR₂, where R=C1-C4 groups and phenyl groups), hydroxyl and alkoxyl groups (—OH, —OR, where R=C1-C4 groups, and phenyl groups), acylamido groups (—NHCOR, where R=C1-C4 groups and phenyl groups), alkylthio and sulfhydryl groups (—SH, —SR, where R=C1-C4 groups and phenyl groups), phenyl group, and carboxylate groups (—(C═O)O—). The EWG include halogens (—I, —Cl, —Br, —F), ammonium groups (—NR₃⁺, where R=C1-C4 groups and phenyl groups), nitro groups (—NO₂), sulfonic acids and sulfonyl groups (—SO₃H, —SO₂R, where R=C1-C4 groups and phenyl groups), cyano group (—CN), formyl and acyl groups (—CHO, —COR, where R=C1-C4 groups and phenyl groups), carboxyl and alkoxycarbonyl groups (—CO₂H, —CO₂R, where R=C1-C4 groups and phenyl groups), and aminocarbonyl groups (—CONH₂, —CONHR, —CONR, where R=C1-C4 groups and phenyl groups), where the C1-C4 groups include all isomers of the C1-C4 groups.

In some embodiments of the first precursor or compound having the formula MₐR_{b}X_{c}, R includes all structural isomers of C1-C4 alkyl groups substituted with a phenyl group, an amino group (—NH₂, —NHR, —NR₂, where R=C1-C3 alkyl group), hydroxyl and alkoxyl groups (—OH, —OR, where R=C1-C3 alkyl group and a phenyl group). In some embodiments of the first precursor or compound having the formula MₐR_{b}X_{c}, R includes C1-C4 alkyl groups substituted at the α-C position by one or two phenyl groups, an amino group (—NH₂, —NHR, —NR₂, where R=C1, C2 or C3 alkyl group), and alkoxyl groups (—OR, where R=C1, C2 or C3 alkyl group).

In some embodiments, X is any substituent readily displaced by the second compound or second precursor to generate an M—OH group, such as a group selected from amines, including dialkylamino and monoalkylamino; alkoxy; carboxylates, halogens, and sulfonates. In some embodiments, the sulfonate group is substituted with one or more amine groups. In some embodiments, the halogen is one or more selected from the group consisting of F, Cl, Br, and I. In some embodiments, the sulfonate group includes a substituted or unsubstituted C1-C3 group.

In some embodiments, R in the formula MₐR_{b}X_{c} includes a C7-C11 aralkyl group, such as a benzyl group, an ethylbenzyl group, a propylbenzyl group, an isopropylbenzyl group, a butylbenzyl group, a sec-butylbenzyl group, or a tert-butylbenzyl group; a C3-C10 cycloalkyl group, such as a cyclobutyl group, a methyl cyclobutyl group, an ethyl cyclobutyl group, a cyclopentyl group, a methyl cyclopentyl, an ethyl cyclopentyl, a cyclohexyl group, a methyl cyclohexyl group, an ethyl cyclohexyl group, a cycloheptyl group, or a cyclooctyl group; a C2-C10 alkoxy group, such as a dimethyl ether group, a methyl dimethyl ether group, an ethyl methyl ether group, a diethyl ether group, a dipropyl ether group, a propyl ethyl ether group, a propyl methyl ether group, a diisopropyl ether group, an isopropyl ethyl ether group, or an isopropyl methyl ether group; or a C2-C10 alkylamino group, such as a methyl dimethyl amino group, a dimethylamino group, a diethylamino group, an ethyl dimethyl amino group, a dipropylamino group, a diisopropylamino group, an isopropyl methyl amino group, or an isopropyl ethyl amino group. In certain embodiments, R includes a cyclopentyl group, a benzyl group, a methyl ether group, an ethyl ether group, a secondary amino group, or a tertiary amino group.

In some embodiments, X in the formula MₐR_{b}X_{c} is a C2-C10 alkylamino group, such as a dimethylamino group, a diethylamino group, a dipropylamino group, a diisopropylamino group, a methyl ethyl amino group, a methyl propyl amino group, an ethyl propyl amino group, or a halogen, such as F, Cl, Br, or I. In some embodiments, X is a dimethylamino group or a diethylamino group, and c=3. In certain embodiments, M is Sn and a is 1. In some embodiments, 1≤a≤2, b≥1, c≥1, and b+c≤4. In some embodiments, b is 1, 2, or 3. In some embodiments, c is 1, 2, or 3. In certain embodiments, b+c=4, and in other embodiments b=1 and c=3.

In some embodiments, the first compound or first precursor includes one or more unsaturated bonds that can be coordinated with a functional group, such as a hydroxyl group, on the surface of the substrate or an intervening underlayer to improve adhesion of the photoresist layer to the substrate or underlayer.

In some embodiments, the second precursor or second compound is one or more selected from the group consisting of water, an amine, a borane, and a phosphine. In some embodiments, the amine has a formula NₚHₙXₘ, where 0≤n≤3, 0≤m≤3, n+m=3 when p is 1, and n+m=4 when p is 2, and each X is independently a halogen selected from the group consisting of F, Cl, Br, and I. In some embodiments, the borane has a formula BₚHₙXₘ, where 0≤n≤3, 0≤m≤3, n+m=3 when p is 1, and n+m=4 when p is 2, and each X is independently halogen selected from the group consisting of F, Cl, Br, and I. In some embodiments, the phosphine has a formula PₚHₙXₘ, where 0≤n≤3, 0≤m≤3, n+m=3, when p is 1, or n+m=4 when p is 2, and each X is independently halogen selected from the group consisting of F, Cl, Br, and I.

In some embodiments, the second precursor or compound is ammonia or hydrazine. The reaction product of the ammonia or hydrazine and the organometallic precursor or compound may form hydrogen bonds that increase the boiling point of the reaction product and prevent emission of the metal photoresist material, thereby preventing metal contamination. The hydrogen bonds can also help prevent moisture effects degrading the photoresist layer quality.

In some embodiments, the first organometallic compound or first organometallic precursor includes a metallic core M⁺ with ligands L attached to the metallic core M⁺, as shown in FIG. 8C. In some embodiments, the metallic core M⁺ is a metal oxide. The ligands L include C3-C12 aliphatic or aromatic groups in some embodiments. The aliphatic or aromatic groups may be unbranched or branched with cyclic, or noncyclic saturated pendant groups containing 1-9 carbons, including alkyl groups, alkenyl groups, and phenyl groups. The branched groups may be further substituted with oxygen or halogen. In some embodiments, the C3-C12 aliphatic or aromatic groups include heterocyclic groups. In some embodiments, the C3-C12 aliphatic or aromatic groups are attached to the metal by an ether or ester linkage. In some embodiments, the C3-C12 aliphatic or aromatic groups include nitrite and sulfonate substituents.

In some embodiments, the organometallic precursor or organometallic compound include a sec-hexyl tris(dimethylamino) tin, t-hexyl tris(dimethylamino) tin, i-hexyl tris(dimethylamino) tin, n-hexyl tris(dimethylamino) tin, sec-pentyl tris(dimethylamino) tin, t-pentyl tris(dimethylamino) tin, i-pentyl tris(dimethylamino) tin, n-pentyl tris(dimethylamino) tin, sec-butyl tris(dimethylamino) tin, t-butyl tris(dimethylamino) tin, i-butyl tris(dimethylamino) tin, n-butyl tris(dimethylamino) tin, sec-butyl tris(dimethylamino) tin, i-propyl tris(dimethylamino) tin, n-propyl tris(diethylamino) tin, and analogous alkyl tris(t-butoxy) tin compounds, including sec-hexyl tris(t-butoxy) tin, t-hexyl tris(t-butoxy) tin, i-hexyl tris(t-butoxy) tin, n-hexyl tris(t-butoxy) tin, sec-pentyl tris(t-butoxy), t-pentyl tris(t-butoxy) tin, i-pentyl tris(t-butoxy) tin, n-pentyl tris(t-butoxy) tin, t-butyl tris(t-butoxy) tin, i-butyl tris(butoxy) tin, n-butyl tris(butoxy) tin, sec-butyl tris(butoxy) tin, i-propyl tris(butoxy) tin, or n-propyl tris(butoxy) tin. In some embodiments, the organometallic precursors or organometallic compounds are fluorinated. In some embodiments, the organometallic precursors or compounds have a boiling point less than about 200° C.

FIG. 8D shows examples of organometallic precursors according to embodiments of the disclosure. In FIG. 8D, Bz is a benzene group.

In some embodiments, the organometallic compound includes tin (Sn), antimony (Sb), bismuth (Bi), indium (In), tellurium (Te), and/or oxides thereof as the metal component, however, the disclosure is not limited to these metals. In other embodiments, additional suitable metals include titanium (Ti), zirconium (Zr), hafnium (Hf), vanadium (V), cobalt (Co), molybdenum (Mo), tungsten (W), aluminum (Al), gallium (Ga), silicon (Si), germanium (Ge), phosphorus (P), arsenic (As), yttrium (Y), lanthanum (La), cerium (Ce), lutetium (Lu), or oxides and combinations thereof. The additional metals can be as alternatives to or in addition to the Sn, Sb, Bi, In, and/or Te.

The particular metal used may significantly influence the absorption of radiation. Therefore, the metal component can be selected based on the desired radiation and absorption cross section. Tin, antimony, bismuth, tellurium, and indium provide strong absorption of extreme ultraviolet light at 13.5 nm. Hafnium provides good absorption of electron beam and extreme UV radiation. Metal compositions including titanium, vanadium, molybdenum, or tungsten have strong absorption at longer wavelengths, to provide, for example, sensitivity to 248 nm wavelength ultraviolet light.

In some embodiments, the photoresist is a chemically amplified resist. Chemically amplified photoresists according to the present disclosure include a polymer along with one or more photoactive compounds (PACs) in a solvent, in some embodiments. In some embodiments, the polymer includes a hydrocarbon structure (such as an alicyclic hydrocarbon structure) that contains one or more groups that will decompose (e.g., acid labile groups) or otherwise react when mixed with acids, bases, or free radicals generated by the PACs (as further described below). In some embodiments, the hydrocarbon structure includes a repeating unit that forms a skeletal backbone of the polymer resin. This repeating unit may include acrylic esters, methacrylic esters, crotonic esters, vinyl esters, maleic diesters, fumaric diesters, itaconic diesters, (meth)acrylonitrile, (meth)acrylamides, styrenes, vinyl ethers, combinations of these, or the like.

In some embodiments, the group which will decompose, otherwise known as an acid labile group (ALG), is attached to the hydrocarbon structure so that, it will react with the acids/bases/free radicals generated by the PACs during exposure. In some embodiments, the group which will decompose is a carboxylic acid group, a fluorinated alcohol group, a phenolic alcohol group, a sulfonic group, a sulfonamide group, a sulfonylimido group, an (alkylsulfonyl) (alkylcarbonyl)methylene group, an (alkylsulfonyl)(alkyl-carbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl methylene group, a tris(alkylsulfonyl)methylene group, combinations of these, or the like. Specific groups that are used for the fluorinated alcohol group include fluorinated hydroxyalkyl groups, such as a hexafluoroisopropanol group in some embodiments. Specific groups that are used for the carboxylic acid group include acrylic acid groups, methacrylic acid groups, or the like. In some embodiments, the polymer in the photoresist composition is a polyhydroxystyrene, polyacrylate, or polymethylmethacrylate based polymer.

In some embodiments, the PACs include photoacid generators, photobase generators, free-radical generators, or the like. In some embodiments in which the PACs are a photoacid generator, the PACs include halogenated triazines, onium salts, diazonium salts, aromatic diazonium salts, phosphonium salts, sulfonium salts, iodonium salts, imide sulfonate, oxime sulfonate, diazodisulfone, disulfone, o-nitrobenzylsulfonate, sulfonated esters, halogenated sulfonyloxy dicarboximides, diazodisulfones, α-cyanooxyamine-sulfonates, imidesulfonates, ketodiazosulfones, sulfonyldiazoesters, 1,2-di(arylsulfonyl)hydrazines, nitrobenzyl esters, and the s-triazine derivatives, combinations of these, or the like.

As one of ordinary skill in the art will recognize, the chemical compounds listed herein are merely intended as illustrated examples of the PACs and are not intended to limit the embodiments to only those PACs specifically described. Rather, any suitable PAC may be used, and all such PACs are fully intended to be included within the scope of the present embodiments.

In some embodiments, the operation S110 of depositing the photoresist composition is performed by a spin coating operation. In some embodiments, the operation S110 of depositing the photoresist composition is performed by a vapor phase deposition operation.

In some embodiments, the vapor phase deposition operation includes atomic layer deposition (ALD) or chemical vapor deposition (CVD). In some embodiments, the ALD includes plasma-enhanced atomic layer deposition (PE-ALD), and the CVD includes plasma-enhanced chemical vapor deposition (PE-CVD), metal-organic chemical vapor deposition (MO-CVD); atmospheric pressure chemical vapor deposition (AP-CVD), and low pressure chemical vapor deposition (LP-CVD). The depositing a photoresist layer includes combining the first compound or first precursor and the second compound or second precursor in a vapor state to form the photoresist composition. In some embodiments, the first compound or first precursor and the second compound or second precursor of the photoresist composition are introduced into the deposition chamber (CVD chamber) at about the same time. In some embodiments, the first compound or first precursor and second compound or second precursor are introduced into the deposition chamber (ALD chamber) in an alternating manner, i.e.—first one compound or precursor then a second compound or precursor, and then subsequently alternately repeating the introduction of the one compound or precursor followed by the second compound or precursor.

In some embodiments, the deposition chamber temperature ranges from about 30° C. to about 400° C. during the deposition operation, and between about 50° C. to about 250° C. in other embodiments. In some embodiments, the pressure in the deposition chamber ranges from about 5 mTorr to about 100 Torr during the deposition operation, and between about 100 mTorr to about 10 Torr in other embodiments. In some embodiments, the plasma power is less than about 1000 W. In some embodiments, the plasma power ranges from about 100 W to about 900 W. In some embodiments, the flow rate of the first compound or precursor and the second compound or precursor ranges from about 100 sccm to about 1000 sccm. In some embodiments, the ratio of the flow of the organometallic compound or precursor to the second compound or precursor ranges from about 1:1 to about 1:10 and ranges from about 1:3 to 1:6 in other embodiments. At operating parameters outside the above recited ranges, unsatisfactory photoresist layers result in some embodiments. In some embodiments, the photoresist layer formation occurs in a single chamber (a one-pot layer formation).

In a CVD process according to some embodiments of the disclosure, two or more gas streams, in separate inlet paths, of an organometallic precursor and a second precursor are introduced to the deposition chamber of a CVD apparatus, where they mix and react in the gas phase, to form a reaction product. The streams are introduced using separate injection inlets or a dual-plenum showerhead in some embodiments. The deposition apparatus is configured so that the streams of organometallic precursor and second precursor are mixed in the chamber, allowing the organometallic precursor and second precursor to react to form a reaction product. Without limiting the mechanism, function, or utility of the disclosure, it is believed that the product from the vapor-phase reaction becomes heavier in molecular weight, and is then condensed or otherwise deposited onto the substrate.

In some embodiments, an ALD process is used to deposit the photoresist layer. During ALD, a layer is grown on a substrate by exposing the surface of the substrate to alternate gaseous compounds (or precursors). In contrast to CVD, the precursors are introduced as a series of sequential, non-overlapping pulses. In each of these pulses the precursor molecules react with the surface in a self-limiting way, so that the reaction terminates once all the reactive sites on the surface are consumed. Consequently, the maximum amount of material deposited on the surface after a single exposure to all of the precursors (a so-called ALD cycle) is determined by the nature of the precursor-surface interaction.

In an embodiment of an ALD process, an organometallic precursor is pulsed to deliver the metal-containing precursor to the substrate surface in a first half reaction. In some embodiments, the organometallic precursor reacts with a suitable underlying species (for example OH or NH functionality on the surface of the substrate) to form a new self-saturating surface. Excess unused reactants and the reaction by-products are removed, by an evacuation-pump down and/or by a flowing an inert purge gas in some embodiments. Then, a second precursor, such as water or ammonia (NH₃), is pulsed to the deposition chamber in some embodiments. The water or NH₃ reacts with the organometallic precursor on the substrate to obtain a reaction product photoresist on the substrate surface. The second precursor also forms self-saturating bonds with the underlying reactive species to provide another self-limiting and saturating second half reaction. A second purge is performed to remove unused reactants and the reaction by-products in some embodiments. Pulses of the first precursor and second precursor are alternated with intervening purge operations until a desired thickness of the photoresist layer 15 is achieved.

In some embodiments, the photoresist layer 15 is formed to a thickness of about 5 nm to about 50 nm, and to a thickness of about 10 nm to about 30 nm in other embodiments. A person of ordinary skill in the art will recognize that additional ranges of thicknesses within the explicit ranges above are contemplated and are within the present disclosure. The thickness can be evaluated using non-contact methods of x-ray reflectivity and/or ellipsometry based on the optical properties of the photoresist layer. The photoresist layer thickness are relatively uniform to facilitate processing. In some embodiments, the variation in thickness of the coating varies by no more than ±25% from the average coating thickness, in other embodiments the photoresist layer thickness varies by no more than ±10% from the average photoresist layer thickness. In some embodiments, such as high uniformity coatings on larger substrates, the evaluation of the photoresist layer uniformity may be evaluated with a 1 centimeter edge exclusion, i.e., the layer uniformity is not evaluated for portions of the coating within 1 centimeter of the edge. A person of ordinary skill in the art will recognize that additional ranges within the explicit ranges above are contemplated and are within the present disclosure.

In some embodiments, the first and second compounds or precursors are delivered into the deposition chamber with a carrier gas. The carrier gas, a purge gas, a deposition gas, or other process gas may contain nitrogen, hydrogen, argon, neon, helium, or combinations thereof.

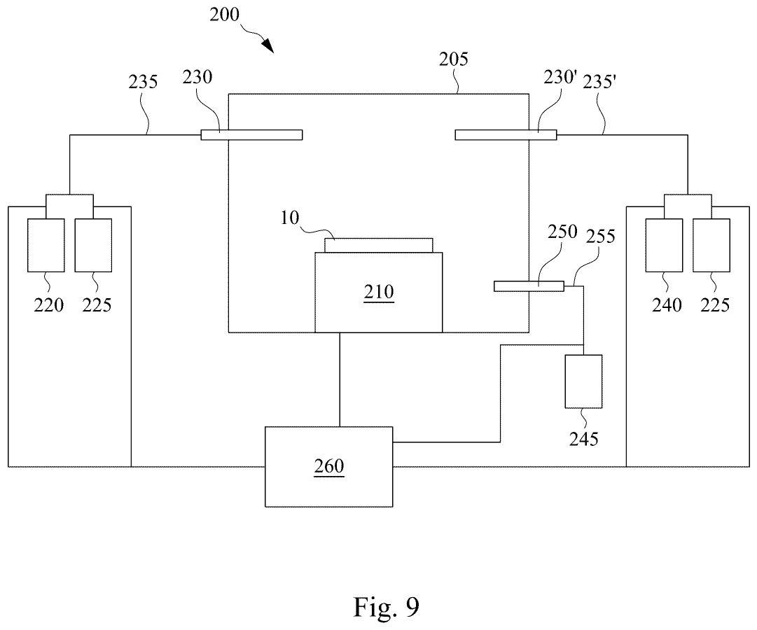

A resist layer deposition apparatus 200 according to some embodiments of the disclosure is shown in FIG. 9. In some embodiments, the deposition apparatus 200 is an ALD or CVD apparatus. The deposition apparatus 200 includes a vacuum chamber 205. A substrate support stage 210 in the vacuum chamber 205 supports a substrate 10, such as silicon wafer. In some embodiments, the substrate support stage 210 includes a heater. A first precursor or compound gas supply 220 and carrier/purge gas supply 225 are connected to an inlet 230 in the chamber via a gas line 235, and a second precursor or compound gas supply 240 and carrier/purge gas supply 225 are connected to another inlet 230′ in the chamber via another gas line 235′ in some embodiments. The chamber is evacuated, and excess reactants and reaction byproducts are removed by a vacuum pump 245 via an outlet 250 and exhaust line 255. In some embodiments, the flow rate or pulses of precursor gases and carrier/purge gases, evacuation of excess reactants and reaction byproducts, pressure inside the vacuum chamber 205, and temperature of the vacuum chamber 205 or wafer support stage 210 are controlled by a controller 260 configured to control each of these parameters.

In some embodiments, the ALD or CVD deposition parameters are varied during the deposition operation to form a photoresist layer having a density gradient. In some embodiments, the density gradient photoresist layer reduces defects, such as scum and bridging; and improves the line width roughness (LWR) and line edge roughness (LER).

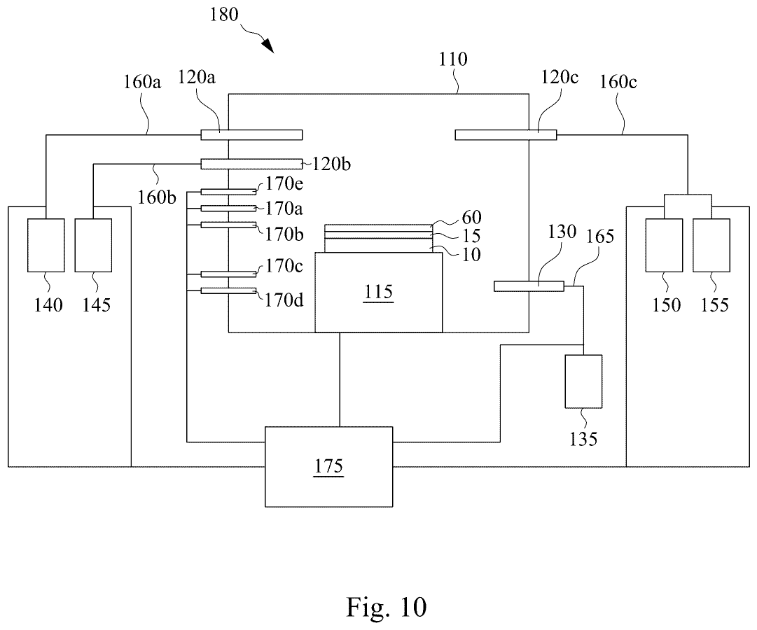

A semiconductor manufacturing apparatus 180 according to embodiments of this disclosure includes a baking chamber 110, and a semiconductor substrate support 115 in the heating chamber, as shown in FIG. 10. The post exposure bake operation S125, or other baking operations, including the pre-exposure baking operation S115, are performed in the baking chamber 110 in some embodiments. In some embodiments, includes multiple inlet ports 120a, 120b, 120c and at least one exhaust port 130. The inlet ports 120a, 120b, 120c are connected to photoresist layer treatment sources 140, 145, 150, 155 via connecting lines 160a, 160b, 160c, respectively. The photoresist layer treatment sources 140, 145 include an oxygen source and a water source, respectively. In some embodiments, additional photoresist layer treatment sources 150, 155 include at least one of an SO₂ source, CO₂ source, NH₃, and an acetic acid source. The additional photoresist treatment material is a gas in some embodiments. In some embodiments, the additional treatment material is an acid or base. The acidic and basic additional treatment can break the bonds of alkyl group substituents in the photoresist composition and thereby promote the crosslinking reaction in the actinic radiation exposed areas 50 of the photoresist layer. The photoresist treatment materials can be in the form of a gas or vapor, or a liquid, such as a fine mist. In some embodiments, the water and oxygen are combined outside of baking chamber and then introduced into the baking chamber as a mixture. In some embodiments, at least one of additional photoresist layer treatment sources 150, 155 contains a carrier gas or a purge, or other process gas. The carrier, purge, or other process gas include nitrogen, hydrogen, argon, neon, helium, or combinations thereof. The size, shape, or number of inlet ports or exhaust ports depends on the chamber design, and number and types of photoresist treatment materials being used in a specific operation.

The substrate support stage 115 includes a heating element in some embodiments to heat the resist-coated substrate 10 during the PEB operation. In some embodiments, the semiconductor substrate support 115 is a hot plate. A vacuum pump 135 is connected to the exhaust port 130 via a connecting line 165 to provide a reduced pressure ambient in some embodiments.

The apparatus also includes a controller 175, programmed to: control a flow of the photoresist layer treatment materials into the baking chamber 110 through the inlet ports 120a, 120b, 120c, control the vacuum pump to control an exhaust flow from the heating chamber through the exhaust port 130 and control a pressure in the baking chamber 110, control the substrate support stage 115 heater to regulate a temperature of the PEB operation, control the concentration of oxygen, water, and any additional photoresist layer treatment materials. In some embodiments, the apparatus includes at least one of an oxygen sensor 170a, a water sensor 170b, a temperature sensor 170c, and a pressure sensor 170d. In some embodiments, the apparatus further includes at least one sensor 170e to sense any additional gases or photoresist treatment materials.

The locations of the inlet ports 120a, 120b, 120c, exhaust port 130, sensors 170a, 170b, 170c, 170d, 170e, substrate support stage 115, and other components of the apparatus shown in FIG. 10 are merely for illustrative purposes, and the various components can be arranged in any feasible or suitable location or arrangement.

In some embodiments, during the PEB operation S125 one or more parameters are controlled, wherein the parameters are selected from: photoresist layer treatment material flow into the baking chamber, exhaust gas flow from the baking chamber, temperature of baking chamber, and concentration of the photoresist layer treatment materials.

In some embodiments, the photoresist layer 15 is heated at a temperature of about 20° C. to about 400° C. for about 20 seconds to about 1500 seconds. In other embodiments, the photoresist layer 15 is heated at a temperature ranging from about 50° C. to about 250° C. for about 50 seconds to about 1000 seconds. At temperatures and heating times less than the disclosed ranges there may be insufficient improvement in photoresist pattern contrast. At temperatures and heating times greater than the disclosed ranges there may be damage to the semiconductor device structures below the photoresist layer.

In some embodiments, a flow rate of the treatment materials flowing into the baking chamber ranges from about 5 L/min to about 40 L/min during the PEB operation S125. In other embodiments, the flow of the treatment material into the heating chamber ranges from about 10 L/min to about 30 L/min.

In some embodiments, a flow rate of exhaust gas from the baking chamber ranges from about 10 L/min to about 50 L/min during the PEB operation S125. In other embodiments, the flow rate of exhaust gas from the baking chamber ranges from about 20 L/min to about 40 L/min. At inlet and exhaust gas flow rates below the disclosed ranges, insufficient treatment of photoresist may result. At flow rates above the disclosed ranges turbulent flow may result and outflow of metal contaminants from the photoresist layer may result.

In some embodiments, the concentration of O₂ and H₂O is varied during the baking the photoresist layer. In some embodiments, the concentration of oxygen is greater than the concentration of water during the PEB operation S125. In some embodiments, the mole ratio of oxygen to a total amount of oxygen and water in the baking chamber is maintained in a range of greater than about 0.2 to less than about 1 during the PEB operation S125. In some embodiments, the mole ratio of oxygen and water is adjusted during the PEB operation S125. In some embodiments, the mole ratio is changed in smooth gradient manner, in other embodiments the ratio of concentration of oxygen and water is changed in a stepwise manner during the PEB operation S125. In some embodiments, the water concentration in the baking chamber is maintained in a range from about 20 ppm to about 2000 ppm during the PEB operation S125. In other embodiments, the water concentration ranges from about 40 ppm to about 1000 ppm. At oxygen and water concentrations outside the disclosed ranges there may be insufficient improvement in photoresist pattern contrast.

In some embodiments, the PEB operation is performed in multiple steps. For example, in one embodiment, a first baking step includes a higher oxygen/water ratio to advance the crosslinking reaction in the actinic radiation exposed areas. Then in a second baking step, the oxygen/water ratio is decreased and an inert carrier gas concentration is increased to increase the hardness of the resist.

In some embodiments, the pressure inside the baking chamber ranges from 1 torr to 700 torr during the PEB operation S125. In other embodiments, the pressure inside the baking chamber ranges from about 10 torr to about 600 torr. At baking chamber pressures outside the disclosed ranges there may be insufficient improvement in photoresist pattern contrast.

In some embodiments, where a dry development operation S145 is performed, the development operation S145 is performed in the same chamber 110 and the PEB operation S125. At least one of the photoresist treatment sources 150, 155 includes a developer gas in some embodiments.

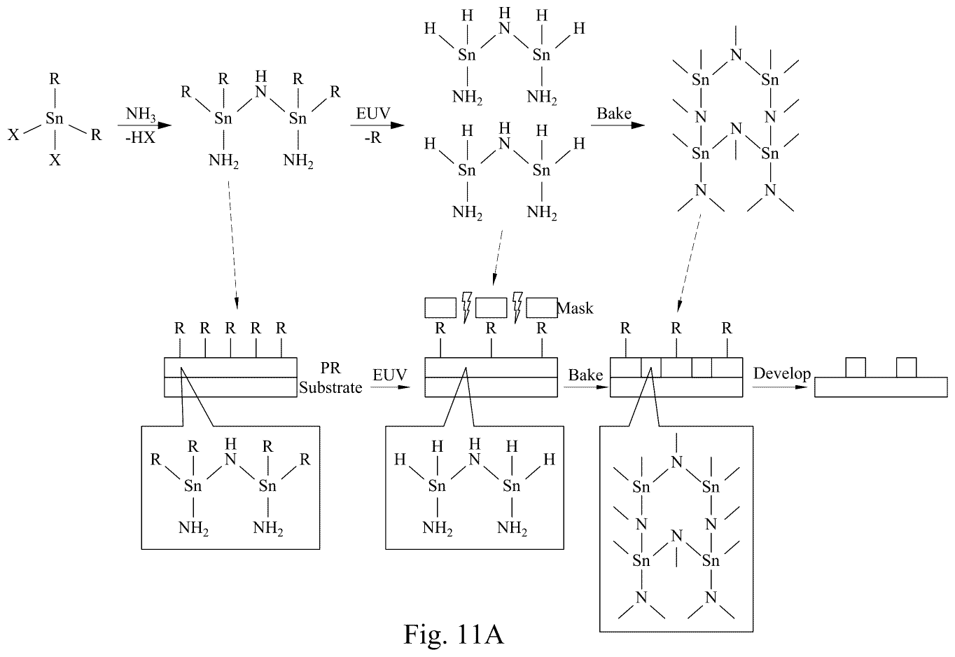

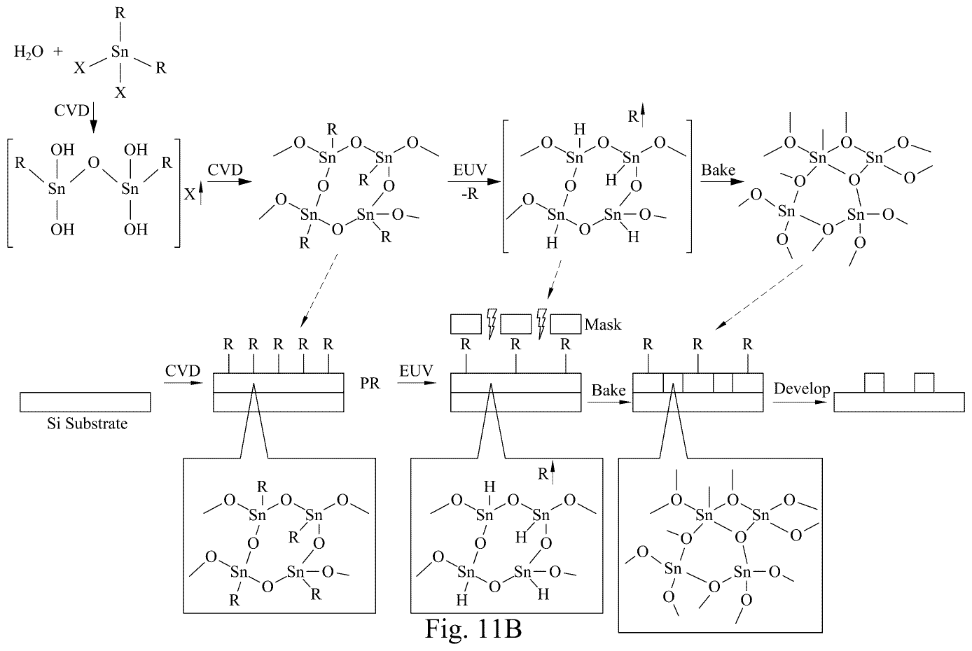

FIG. 11A shows a reaction the photoresist composition components undergo as a result of exposure to actinic radiation and heating according to an embodiment of the disclosure. FIG. 11A shows an exemplary chemical structure of the photoresist layer (PR) at various stages of the photoresist patterning method according to embodiments of the disclosure. As shown in FIG. 11A, the photoresist composition includes an organometallic compound, for example SnX₂R₂, and a second compound, for example ammonia (NH₃). When the organometallic compound and the ammonia are combined, the organometallic compound reacts with some of the ammonia in the vapor phase to form a reaction product with amine groups attached to the metal (Sn) of the organometallic compound. The amine groups in the as deposited photoresist layer have hydrogen bonds that can substantially increase the boiling point of the deposited photoresist layer and prevent the outgassing of metal-containing photoresist material, thereby preventing contamination of the deposition chamber and semiconductor device processing equipment by the metal in the metal-containing photoresist. Moreover, the hydrogen bonds of the amine groups can control the effect moisture has on photoresist layer quality.

When subsequently exposed to extreme ultraviolet radiation using a mask, the organometallic compound absorbs the extreme ultraviolet radiation and one or more organic R groups are cleaved from the organometallic compound to form an amino metallic compound in the radiation exposed areas. Then, when the post-exposure bake (PEB) performed, the amino metallic compounds crosslink through the amine groups in some embodiments, as shown in FIG. 11A. In some embodiments, partial crosslinking of the amino metallic compounds occurs as a result of the exposure to extreme ultraviolet radiation. The selectively exposed photoresist is subsequently developed, and the crosslinked radiation exposed pattern remains over the substrate while the radiation unexposed areas are removed during the development.

FIG. 11B shows a reaction the photoresist composition components undergo as a result of exposure to actinic radiation and heating according to an embodiment of the disclosure. FIG. 11B shows an exemplary chemical structure of the photoresist layer (PR) at various stages of the photoresist patterning method according to embodiments of the disclosure. As shown in FIG. 11B, the photoresist composition includes an organometallic compound, for example SnX₃R, and a second compound, for example water (H₂O). When the organometallic compound and the water (vapor) are combined in a CVD process, the organometallic compound reacts with some of the water in the vapor phase to form a reaction product with hydroxyl groups (—OH) attached to the metal (Sn) of the organometallic compound, by substituting X with —OH. Further, the reaction product is subjected to a CVD process to form a film over the substrate, in which the hydroxy metallic compounds crosslink through the hydroxyl groups in some embodiments.

The crosslinked structure in the as deposited photoresist layer can substantially increase the boiling point of the deposited photoresist layer and prevent the outgassing of metal-containing photoresist material, thereby preventing contamination of the deposition chamber and semiconductor device processing equipment by the metal in the metal-containing photoresist.

When subsequently exposed to extreme ultraviolet radiation using a mask, the organometallic compound absorbs the extreme ultraviolet radiation and one or more organic R groups are cleaved from the organometallic compound to form a crosslinked metal oxide compound in the radiation exposed areas. In some embodiments, hydrogen is left when the organic R groups are cleaved. Then, when the post-exposure bake (PEB) performed, the crosslinked metal oxide compounds further crosslink through the hydrogen and oxygen in some embodiments, as shown in FIG. 11B. In some embodiments, partial crosslinking occurs as a result of the exposure to extreme ultraviolet radiation. The selectively exposed photoresist is subsequently developed, and the crosslinked radiation exposed pattern remains over the substrate while the radiation unexposed areas are removed during the development.

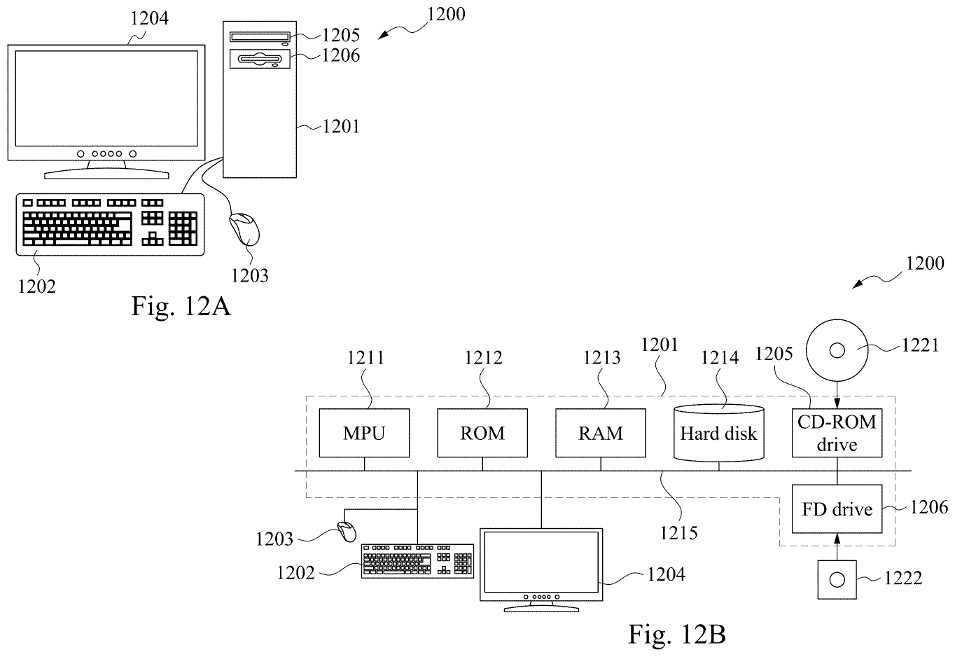

FIGS. 12A and 12B illustrate a controller for controlling the post-exposure baking operation S125, and other operations, such as the pre-exposure baking operation S115 and development operation S145. In some embodiments, a computer system 1200 is used as the controller for controlling the baking operations. In some embodiments, the same computer system 1200 is used as the controller 260 for controlling the photoresist deposition operation S110 and the controller 175 for controlling the PEB operation S125. All of or a part of the processes, method and/or operations of the foregoing embodiments can be realized using computer hardware and computer programs executed thereon. In FIG. 12A, a computer system 1200 is provided with a computer 1201 including an optical disk read only memory (e.g., CD-ROM or DVD-ROM) drive 1205 and a magnetic disk drive 1206, a keyboard 1202, a mouse 1203, and a monitor 1204.

FIG. 12B is a diagram showing an internal configuration of the computer system 1200. In FIG. 12B, the computer 1201 is provided with, in addition to the optical disk drive 1205 and the magnetic disk drive 1206, one or more processors, such as a micro processing unit (MPU) 1211, a ROM 1212 in which a program such as a boot up program is stored, a random access memory (RAM) 1213 that is connected to the MPU 1211 and in which a command of an application program is temporarily stored and a temporary storage area is provided, a hard disk 1214 in which an application program, a system program, and data are stored, and a bus 1215 that connects the MPU 1211, the ROM 1212, and the like. Note that the computer 1201 may include a network card (not shown) for providing a connection to a LAN.

The program for causing the computer system 1200 to execute the functions of an apparatus for baking the coated substrates in any of the foregoing embodiments may be stored in an optical disk 1221 or a magnetic disk 1222, which are inserted into the optical disk drive 1205 or the magnetic disk drive 1206, and transmitted to the hard disk 1214. Alternatively, the program may be transmitted via a network (not shown) to the computer 1201 and stored in the hard disk 1214. At the time of execution, the program is loaded into the RAM 1213. The program may be loaded from the optical disk 1221 or the magnetic disk 1222, or directly from a network. The program does not necessarily have to include, for example, an operating system (OS) or a third party program to cause the computer 1201 to execute the baking operations in the foregoing embodiments. The program may only include a command portion to call an appropriate function (module) in a controlled mode and obtain desired results.

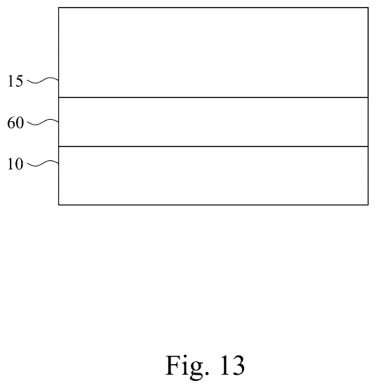

In some embodiments, a target layer 60 to be patterned is disposed over the substrate prior to forming the resist layer 15, as shown in FIG. 13. In some embodiments, the target layer 60 is a semiconductor layer; a conductive layer, such as a metallization layer; or a dielectric layer, such as a passivation layer disposed over a metallization layer. In some embodiments where the target layer 60 is a metallization layer, the target layer 60 is formed of a conductive material using metallization processes, and metal deposition techniques, including electroplating, chemical vapor deposition, atomic layer deposition, and physical vapor deposition (sputtering). Likewise, in some embodiments where the target layer 60 is a dielectric layer, the target layer 60 is formed by dielectric layer formation techniques, including thermal oxidation, chemical vapor deposition, atomic layer deposition, and physical vapor deposition. In some embodiments, the target layer 60 is a bottom antireflective coating (BARC) layer made of an organic polymer or a silicon containing material.

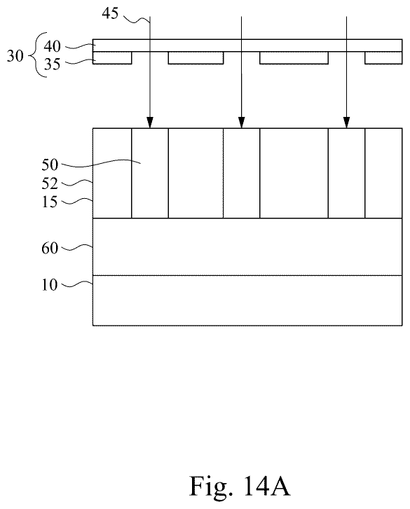

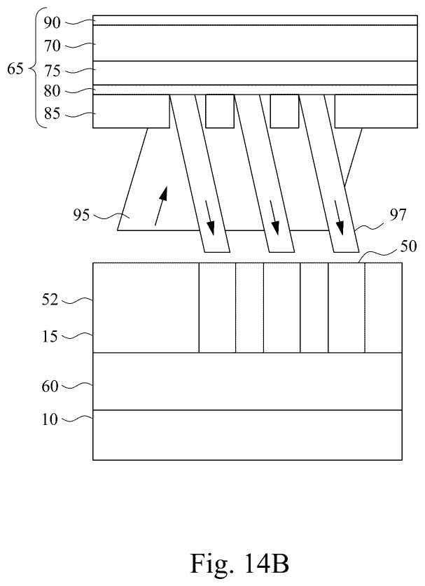

The photoresist layer 15 is subsequently selectively exposed or patternwise exposed to actinic radiation 45/97 to form exposed regions 50 and unexposed regions 52, in the photoresist layer, as shown in FIGS. 14A and 14B, and described herein in relation to FIGS. 3A and 3B.

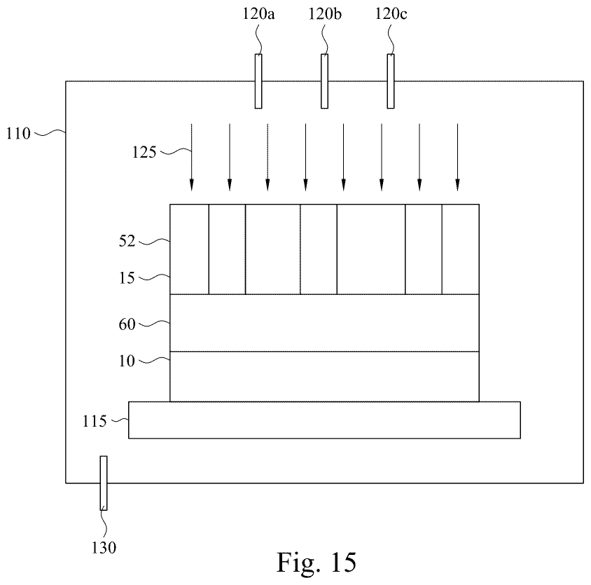

Then, as shown in FIG. 15, the selectively exposed or patternwise exposed photoresist layer 15 undergoes a post exposure baking operation, as described herein in relation to FIG. 4.

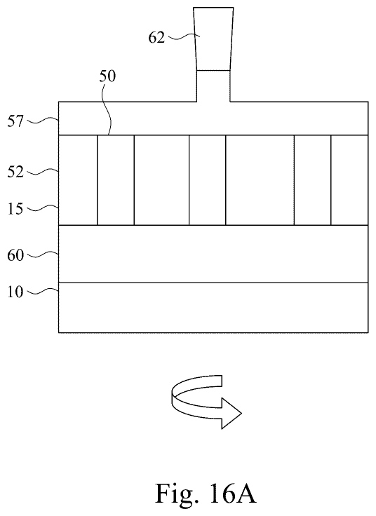

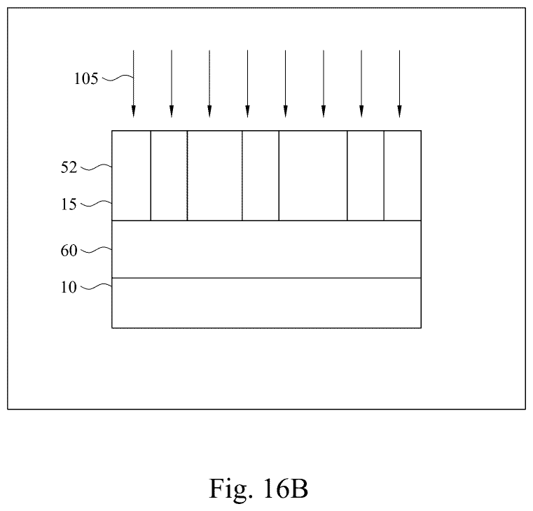

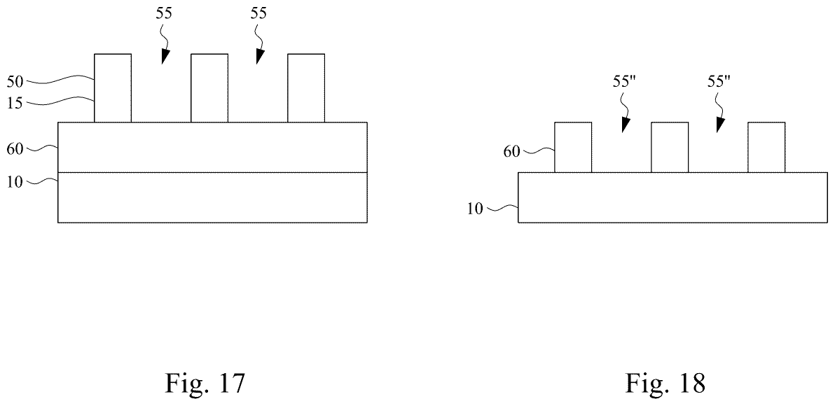

After the PEB operation S125, the photoresist layer 15 is developed, as shown in FIGS. 16A and 16B to form a pattern of photoresist openings 55, as shown in FIG. 17. The unexposed photoresist regions 52 are developed by dispensing a developer 57 from a dispenser 62, as shown in FIG. 16A, or by a dry development operation, as shown in FIG. 16B to form the photoresist pattern 55, as shown in FIG. 17. The development operation is similar to that explained herein with reference to FIGS. 5A, 5B, and 6.

Then, as shown in FIG. 17, the pattern 55 in the photoresist layer 15 is transferred to the target layer 60 using a suitable etching operation and the photoresist layer is removed, as explained with reference to FIG. 7 to form pattern 55′ in the target layer 60.

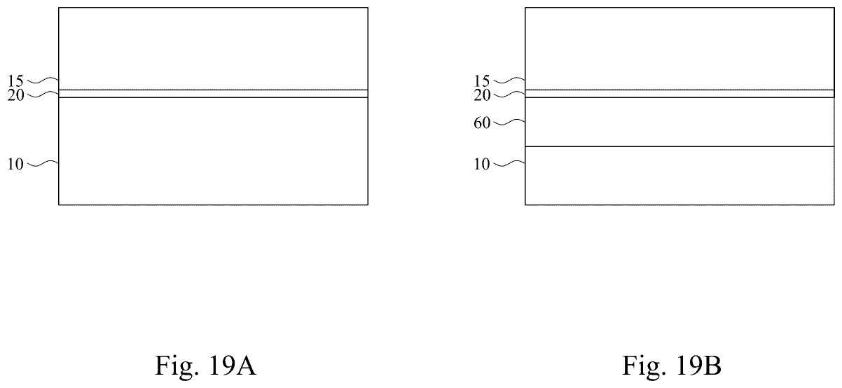

In some embodiments, a resist underlayer 20 is formed over the substrate 10 or target layer 60 before the resist layer 15 is formed, as shown in FIGS. 19A and 19B. The resist underlayer 20 improves the adhesion of the resist layer 15 to the substrate or target layer in some embodiments. In some embodiments, the resist underlayer 20 functions as a bottom anti-reflective coating. The BARC absorbs actinic radiation that passes through the photoresist layer, thereby preventing the actinic radiation from reflecting off the substrate or target layer and exposing unintended portions of the photoresist layer. Thus, the BARC improves line width roughness and line edge roughness of the photoresist pattern. In some embodiments, the BARC is made of an organic polymer; an inorganic polymer, such as a polysiloxane; or silicon-containing layer, such as a silicon oxide. The structures shown in FIGS. 19A and 19B subsequently undergo the operations disclosed herein in reference to FIG. 1 to form semiconductor devices.

Other embodiments include other operations before, during, or after the operations described above. In an embodiment, the method includes forming field effect transistor structures, including fin field effect (FinFET) transistors and gate-all-around field effect (GAA FET) transistors. In some embodiments, a plurality of active fins are formed on the semiconductor substrate. Such embodiments, further include etching the substrate through the openings of the patterned hard mask to form trenches in the substrate; filling the trenches with a dielectric material; performing a chemical mechanical polishing (CMP) process to form shallow trench isolation (STI) features; and epitaxy growing or recessing the STI features to form fin-like active regions. In another embodiment, the method includes other operations to form a plurality of gate electrodes on the semiconductor substrate. The method may further include forming gate spacers, doped source/drain regions, contacts for gate/source/drain features, etc. In another embodiment, a target pattern is to be formed as metal lines in a multilayer interconnection structure. For example, the metal lines may be formed in an inter-layer dielectric (ILD) layer of the substrate, which has been etched to form a plurality of trenches. The trenches may be filled with a conductive material, such as a metal; and the conductive material may be polished using a process such as chemical mechanical planarization (CMP) to expose the patterned ILD layer, thereby forming the metal lines in the ILD layer. The above are non-limiting examples of devices/structures that can be made and/or improved using the method described herein.

As described above, the semiconductor wafer may be an intermediate structure fabricated during processing of an IC, or a portion thereof, that may include logic circuits, memory structures, passive components (such as resistors, capacitors, and inductors), and active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, three-dimensional (3D) FETs, other memory cells, and combinations thereof.

The embodiments of the present disclosure offer advantages over existing art, though it is understood that other embodiments may offer different advantages, not all advantages are necessarily discussed herein, and that no particular advantage is required for all embodiments. Oxygen added to the PEB operation promotes photoresist crosslinking in the actinic radiation exposed areas, while water added to the PEB operation suppresses crosslinking reactions in the non-exposed areas. In some embodiments, additional photoresist treatment materials added to the PEB operation promote the crosslinking reaction in the actinic radiation exposed areas. Embodiments of this disclosure provide improved contrast between the exposed and non-exposed regions of the photoresist layer during semiconductor device fabrication. Embodiments of the disclosure provide improved local critical dimension uniformity. Embodiments of the disclosure provide improvement in the pattern density induced loading effect. Embodiments of this disclosure provide improved integrity of the photoresist pattern and decreased line width roughness and line edge roughness, and scum reduction. Embodiments of the disclosure allow reduced exposure doses.

In an embodiment of the disclosure, a method of manufacturing a semiconductor device includes depositing a photoresist composition over a target layer on a substrate to form a photoresist layer. The photoresist layer is selectively exposed to actinic radiation. A vacuum is applied to the photoresist layer after selectively exposing the photoresist layer. O₂ and H₂O are introduced to the selectively exposed photoresist layer. The selectively exposed photoresist layer is baked. The photoresist layer is developed after baking the photoresist layer. The target layer is etched using the photoresist layer as an etch mask. In an embodiment, the photoresist composition is deposited by a spin coating operation. In an embodiment, the actinic radiation is extreme ultraviolet radiation. In an embodiment, a concentration of at least one of the O₂ and H₂O introduced to the selectively exposed photoresist layer is varied during the baking the selectively exposed photoresist layer. In an embodiment, the photoresist layer is baked in a baking chamber and a pressure inside the baking chamber ranges from 1 torr to 700 torr during the baking the photoresist layer. In an embodiment, the pressure in the baking chamber is varied during the baking the photoresist layer. In an embodiment, an additional gas is introduced into the baking chamber during the baking the photoresist layer. In an embodiment, the additional gas is at least one selected from sulfur dioxide, carbon dioxide, ammonia, and acetic acid. In an embodiment, the photoresist layer is baked while introducing O₂ and H₂O to the selectively exposed photoresist layer. In an embodiment, the photoresist composition includes a metal.

Another embodiment of the disclosure is a method of manufacturing a semiconductor device including depositing a metallic resist layer over a substrate and patternwise exposing the resist layer to actinic radiation. A vacuum is applied to the patternwise exposed resist layer. A gaseous mixture of oxygen and water is applied to the patternwise exposed resist layer and the patternwise exposed resist layer is heated. The resist layer is developed using a dry developer after the heating the patternwise exposed resist layer to form a patterned resist layer. A portion of the substrate exposed by the patterned resist layer is removed. In an embodiment, a concentration of at least one of the oxygen and the water applied to the patternwise exposed photoresist layer is varied during the heating the patternwise exposed resist layer. In an embodiment, the applying the vacuum, applying the gaseous mixture, and heating the patternwise exposed resist layer are performed in a single chamber. In an embodiment, a pressure in the chamber is varied during the heating the patternwise exposed resist layer. In an embodiment, an additional gas is introduced into the chamber during the heating the patternwise exposed resist layer. In an embodiment, the additional gas is at least one selected from sulfur dioxide, carbon dioxide, ammonia, and acetic acid.

Another embodiment of the disclosure is a method of manufacturing a semiconductor device, including combining a first resist precursor and a second resist precursor to form a resist layer over a substrate thereby forming a resist-coated substrate. The resist layer is selectively exposed to actinic radiation to form a latent image in the resist layer. After selectively exposing the resist layer, transferring the resist-coated substrate into a chamber. A pressure inside the chamber is reduced after transferring the resist-coated substrate into the chamber. The resist-coated substrate is baked in the chamber. A mixture of O₂ and H₂O is applied to the resist-coated substrate in the chamber, and a developer is applied to the resist-coated substrate to form a patterned resist layer after applying the mixture of O₂ and H₂O to the resist-coated substrate. In an embodiment, applying a developer to the resist-coated substrate includes applying a dry developer to the resist-coated substrate. In an embodiment, the developer is applied to the resist-coated substrate in the chamber. In an embodiment, the method includes etching the substrate using the patterned resist layer as an etching mask.

Another embodiment of the disclosure is a semiconductor device manufacturing apparatus including: a chamber, a vacuum pump connected to the chamber, a semiconductor substrate support in the chamber, at least one gas flow inlet in the chamber, at least one gas flow exhaust in the chamber, a heater, and a controller. The controller is programmed to: control the vacuum pump, control a flow of a first gas into the chamber through the at least one gas flow inlet, control a flow of a second gas into the chamber through the at least one gas flow inlet, control exhaust gas flow from the chamber through the gas flow exhaust, control a temperature inside the chamber, and control a pressure in the chamber. In an embodiment, the semiconductor substrate support includes a heating element. In an embodiment, the controller is programmed to control the gas flow of the first gas and the second gas into the chamber so that a concentration of the first gas in the chamber is greater than a concentration of the second gas in the chamber. In an embodiment, the controller is further programmed to control a flow of a third gas into the chamber through the at least one gas flow inlet, wherein the third gas is different from the first gas and the second gas. In an embodiment, the semiconductor device manufacturing apparatus includes a pressure sensor disposed in the chamber, wherein the pressure sensor is in communication with the controller. In an embodiment, the semiconductor device manufacturing apparatus includes a temperature sensor disposed in the chamber, wherein the temperature sensor is in communication with the controller. In an embodiment, the semiconductor device manufacturing apparatus includes an oxygen sensor disposed in the chamber, wherein the oxygen sensor is in communication with the controller. In an embodiment, the semiconductor device manufacturing apparatus includes a water sensor, wherein the water sensor is in communication with the controller.

Another embodiment of the disclosure is a semiconductor device manufacturing apparatus including: a vacuum chamber, a vacuum pump connected to the vacuum chamber, a semiconductor substrate support in the vacuum chamber, a gas flow inlet in the vacuum chamber, a gas flow exhaust in the vacuum chamber, a heater, and a controller. The controller is programmed to: control the vacuum pump, control a flow of oxygen into the vacuum chamber, control a flow of water vapor into the vacuum chamber, control exhaust gas flow from the vacuum chamber through the gas flow exhaust, control a temperature inside the vacuum chamber, control a pressure in the vacuum chamber, and maintain a higher concentration of oxygen than a concentration of water vapor in the vacuum chamber. In an embodiment, the controller is further programmed to control the flow of an additional gas into the vacuum chamber. In an embodiment, the controller is programmed to maintain a mole ratio of oxygen to a total amount of oxygen and water in the chamber in a range of greater than 0.2 to less than 1. In an embodiment, the controller is programmed to maintain a water concentration in the chamber in a range from 20 ppm to 2000 ppm. In an embodiment, the controller is programmed to maintain a temperature inside the chamber in a range from 20° C. to 400° C. In an embodiment, the controller is programmed to maintain a pressure inside the chamber in a range from 1 torr to 700 torr. In an embodiment, the controller is programmed to vary at least one of the pressure inside the chamber, temperature inside the chamber, and gas concentration inside the chamber.

Another embodiment of the disclosure is a semiconductor device manufacturing apparatus, includes: a chamber, a vacuum pump connected to the chamber, a substrate support disposed in the chamber, a gas flow inlet in a wall of the chamber, a gas flow exhaust in a wall of chamber connected to the vacuum pump, and a controller. The controller is programmed to: control a concentration of oxygen and water vapor in the chamber so that a molar concentration of oxygen is greater than the molar concentration of water in the chamber, control a temperature inside the chamber, and control a pressure in the chamber. In an embodiment, the controller is further programmed to vary the pressure inside the chamber while a substrate is being processed inside the chamber. In an embodiment, the controller is programmed to vary the temperature inside the chamber while a substrate is being processed inside the chamber. In an embodiment, the controller is programmed to vary the concentration of oxygen and water vapor inside the chamber while a substrate is being processed inside the chamber. In an embodiment, the semiconductor device manufacturing apparatus includes at least one of a pressure sensor, an oxygen sensor, a water sensor, and a temperature sensor.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
depositing a photoresist composition over a target layer on a substrate to form a photoresist layer;
selectively exposing the photoresist layer to actinic radiation;
applying a vacuum to the photoresist layer after selectively exposing the photoresist layer;
introducing O₂ and H₂O to the selectively exposed photoresist layer;
baking the selectively exposed photoresist layer;
developing the photoresist layer after baking the photoresist layer; and
etching the target layer using the photoresist layer as an etch mask.

2. The method according to claim 1, wherein the photoresist composition is deposited by a spin coating operation.

3. The method according to claim 1, wherein the actinic radiation is extreme ultraviolet radiation.

4. The method according to claim 1, wherein a concentration of at least one of the O₂ and H₂O introduced to the selectively exposed photoresist layer is varied during the baking the selectively exposed photoresist layer.

5. The method according to claim 1, wherein the photoresist layer is baked in a baking chamber and a pressure inside the baking chamber ranges from 1 torr to 700 torr during the baking the photoresist layer.

6. The method according to claim 5, wherein the pressure in the baking chamber is varied during the baking the photoresist layer.

7. The method according to claim 5, wherein an additional gas is introduced into the baking chamber during the baking the photoresist layer.

8. The method according to claim 7, wherein the additional gas is at least one selected from sulfur dioxide, carbon dioxide, ammonia, and acetic acid.

9. The method according to claim 1, wherein the photoresist layer is baked while introducing O₂ and H₂O to the selectively exposed photoresist layer.

10. The method according to claim 1, wherein the photoresist composition comprises a metal.

11. A method of manufacturing a semiconductor device, comprising:
depositing a metallic resist layer over a substrate;
patternwise exposing the resist layer to actinic radiation;
applying a vacuum to the patternwise exposed photoresist layer;
applying a gaseous mixture of oxygen and water to the patternwise exposed resist layer;
heating the patternwise exposed resist layer;
developing the resist layer using a dry developer after the heating the patternwise exposed resist layer to form a patterned resist layer; and
removing a portion of the substrate exposed by the patterned resist layer.

12. The method according to claim 11, wherein a concentration of at least one of the oxygen and the water applied to the patternwise exposed photoresist layer is varied during the heating the patternwise exposed resist layer.

13. The method according to claim 11, wherein the applying the vacuum, applying the gaseous mixture, and heating the patternwise exposed resist layer are performed in a single chamber.

14. The method according to claim 13, wherein a pressure in the chamber is varied during the heating the patternwise exposed resist layer.

15. The method according to claim 13, wherein an additional gas is introduced into the chamber during the heating the patternwise exposed resist layer.

16. The method according to claim 15, wherein the additional gas is at least one selected from sulfur dioxide, carbon dioxide, ammonia, and acetic acid.

17. A semiconductor device manufacturing apparatus, comprising:
a chamber;
a vacuum pump connected to the chamber;
a semiconductor substrate support in the chamber;
at least one gas flow inlet in the chamber;
at least one gas flow exhaust in the chamber;
a heater; and
a controller, programmed to:
control the vacuum pump,
control a flow of a first gas into the chamber through the at least one gas flow inlet,
control a flow of a second gas into the chamber through the at least one gas flow inlet,
control exhaust gas flow from the chamber through the gas flow exhaust,
control a temperature inside the chamber, and
control a pressure in the chamber.

18. The semiconductor device manufacturing apparatus of claim 17, wherein the semiconductor substrate support includes a heating element.

19. The semiconductor device manufacturing apparatus of claim 17, wherein the controller is programmed to control the gas flow of the first gas and the second gas into the chamber so that a concentration of the first gas in the chamber is greater than a concentration of the second gas in the chamber.

20. The semiconductor device manufacturing apparatus of claim 17, wherein the controller is further programmed to control a flow of a third gas into the chamber through the at least one gas flow inlet, wherein the third gas is different from the first gas and the second gas.
